(19) United States
(12) Patent Application Publication
(10) Pub. No.: US 2008/0257494 A1
(43) Pub. Date: Oct. 23, 2008

(54) SUBSTRATE PROCESSING APPARATUS

(75) Inventors: Daisuke Hayashi, Nirasaki-shi (JP); Kazuya Nagaseki, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/022,803

(22) Filed: Jan. 30, 2008

Related U.S. Application Data
(60) Provisional application No. 60/908,427, filed on Mar. 28, 2007.

(30) Foreign Application Priority Data
Jan. 31, 2007 (JP) 2007-022331

(51) Int. Cl. C23F 1/02; C23C 16/52

(52) U.S. Cl. 156/345.27; 118/724

(57) ABSTRACT

A substrate processing apparatus capable of rapidly raising and lowering the processing temperature of a substrate. The substrate processing apparatus has a mounting stage adapted to be mounted with a substrate and to control the processing temperature of the mounted substrate. The mounting stage comprises a temperature control device disposed in a mounting surface of the mounting stage for mounting the substrate thereon, a coolant inflow chamber into which a coolant is flowed, and a heat transmission/insulation switch-over chamber disposed between the temperature control device and the coolant inflow chamber so that a heat-transmitting gas is flowed into and vacuum-exhausted from the heat transmission/insulation switch-over chamber. The temperature control device has therein a gas inflow chamber into which a hot gas is flowed.

### BACKGROUND OF THE INVENTION

1. Field of the Invention

The present invention relates to a substrate processing apparatus, and more particularly, to a substrate processing apparatus having a mounting stage for a substrate to be mounted on and for controlling the processing temperature of the mounted substrate.

2. Description of the Related Art

In a method for manufacturing semiconductor devices from a silicon wafer (hereinafter simply referred to as the “wafer”), there are successively and cyclically carried out a film formation step, such as chemical vapor deposition (CVD), wherein a conductive film or an insulating film is formed on a surface of the wafer; a lithography step wherein desired patterns of a photoresist layer is formed on the conductive film or the insulating film thus formed; and an etching step wherein the conductive film is shaped into gate electrodes or wiring trenches and contact holes are formed in the insulating film by plasma produced from a processing gas using the photoresist layer as a mask.

In some electronic device manufacturing method, a polysilicon layer formed on a wafer is etched. In this case, a deposit film composed primarily of SiO₂ is formed on the side surfaces of trenches (grooves) formed in the wafer.

This deposit film can cause problems, such as a conduction failure, for electronic devices and hence must be removed. As a method for deposit layer removal, there is known a substrate processing method wherein a chemical oxide removal (COR) treatment and a post heat treatment (PHT) are performed on the wafer. The COR treatment causes SiO₂ in the deposit layer to chemically react with gas molecules to produce a product. The PHT treatment heats up and sublimates the product produced on the wafer due to the chemical reaction caused by the COR treatment, thereby removing the product from the wafer.

As a substrate processing apparatus for implementing this substrate processing method comprised of COR and PHT treatments, there is known a substrate processing apparatus having a chemical reaction treatment apparatus and a heat treatment apparatus connected thereto (see, for example, Japanese Patent Laid-open No. 2005-39185).

On the other hand, it is under consideration from the viewpoint of efficient treatments and cost reductions to perform both a chemical reaction treatment and a heating treatment in one substrate processing apparatus. In this case, the temperature of the mounting stage for mounting a wafer thereon within the substrate processing apparatus must be changed depending on the type of treatment since the processing temperature of the wafer is controlled by the temperature of the mounting stage.

However, when the temperature of the mounting stage is changed depending on the type of treatment, a heater for raising the temperature of the mounting stage and a coolant channel for lowering the temperature must be provided in combination within the mounting stage. Since the heater has a large heat capacity, the heat capacity of the mounting stage becomes larger as the result of providing the heater within the mounting stage. For this reason, it is not possible to rapidly raise the temperature of the mounting stage, though the temperature can be increased using the heater. In addition, a coolant made to pass through the coolant channel is a liquid and, therefore, cannot be made to pass therethrough at a high rate. For this reason, it is not possible to rapidly lower the temperature of the mounting stage, though the temperature can be decreased using the coolant channel.

Accordingly, it is not possible to rapidly change the temperature of the mounting stage within one substrate processing apparatus. It is therefore not possible to rapidly raise and lower the processing temperature of a wafer.

### SUMMARY OF THE INVENTION

The present invention provides a substrate processing apparatus capable of rapidly raising and lowering the processing temperature of a substrate.

According to a first aspect of the present invention, there is provided with a substrate processing apparatus having a mounting stage adapted to be mounted with a substrate and to control the processing temperature of the mounted substrate, the mounting stage comprising: a temperature control device disposed in a mounting surface of the mounting stage for mounting the substrate thereon; a coolant inflow chamber into which a coolant is flowed; and a heat transmission/insulation switch-over chamber disposed between the temperature control device and the coolant inflow chamber so that a heat-transmitting gas is flowed into and vacuum-exhausted from the heat transmission/insulation switch-over chamber, wherein the temperature control device has therein a gas inflow chamber into which a hot gas is flowed.

According to the aforementioned first aspect of the present invention, the temperature of the coolant flowed into the coolant inflow chamber is transferred to the temperature control device as the result of a heat-transmitting gas being flowed into the heat transmission/insulation switch-over chamber, and the temperature of the temperature control device is rapidly lowered by the temperature of the heat-transferred coolant. On the other hand, the transfer of the temperature of the coolant flowed into the coolant inflow chamber is cut off as the result of the heat-transmitting gas in the heat transmission/insulation switch-over chamber being vacuum-exhausted, and the temperature of the temperature control device is rapidly raised by the temperature of the hot gas flowed into the gas inflow chamber. In addition, the temperature of the substrate within the substrate processing apparatus is controlled by the temperature of the temperature control device. Consequently, it is possible to rapidly raise and lower the processing temperature of the substrate within a single substrate processing apparatus.

A material composing a wall delimiting the gas inflow chamber can be any one of carbon, aluminum, copper, brass, iron, silver, aluminum nitride, and silicon carbide.

With this arrangement, it is possible to increase the thermal conductance of the temperature control device since carbon, aluminum, copper, brass, iron, silver, aluminum nitride, and silicon carbide have a large heat conductivity and a small specific heat capacity.

The thickness of the wall can be not more than 2 mm. With this arrangement, it is possible to reduce the mass of the temperature control device, thereby reliably reducing the heat capacity of the temperature control device.

The temperature of the hot gas can be not less than 200° C.

With this arrangement, it is possible to rapidly raise the temperature of the temperature control device, thereby rapidly raising the processing temperature of a substrate.

According to a second aspect of the present invention, there is provided a substrate processing apparatus having a mounting stage adapted to be mounted with a substrate and to control the processing temperature of the mounted substrate, the mounting stage comprising a temperature control device disposed in a mounting surface of the mounting stage for mounting the substrate thereon, wherein the temperature control device has therein a gas inflow chamber into which a cold gas or a hot gas is flowed.

According to the aforementioned second aspect of the present invention, the temperature of the temperature control device is rapidly lowered by the temperature of the cold gas as the result of the cold gas being flowed into the gas inflow chamber. On the other hand, the temperature of the temperature control device is rapidly raised by the temperature of the hot gas as the result of the hot gas being flowed into the gas inflow chamber. In addition, the temperature of the substrate within the substrate processing apparatus is controlled by the temperature of the temperature control device. Consequently, it is possible to rapidly raise and lower the processing temperature of the substrate within a single substrate processing apparatus.

A material composing a wall delimiting the gas inflow chamber can be any one of carbon, aluminum, copper, brass, iron, silver, aluminum nitride, and silicon carbide.

With this arrangement, it is possible to increase the thermal conductance of the temperature control device since carbon, aluminum, copper, brass, iron, silver, aluminum nitride, and silicon carbide have a large heat conductivity and a small specific heat capacity.

The thickness of the wall is not more than 2 mm. With this arrangement, it is possible to reduce the mass of the temperature control device, thereby reliably reducing the heat capacity of the temperature control device.

The temperature of the cold gas can be not more than −20° C. and the temperature of the hot gas can be not less than 200° C.

With this arrangement, it is possible to rapidly raise and lower the temperature of the temperature control device, thereby rapidly raising and lowering the processing temperature of the substrate.

The cold gas can be a dry gas.

With this arrangement, it is possible to efficiently flow the cold gas into the gas inflow chamber. The above and other objects, features, and advantages of the invention will become more apparent from the following detailed description taken in conjunction with the accompanying drawings.

### BRIEF DESCRIPTION OF THE DRAWINGS

FIG. 1 is a plan view schematically showing the configuration of a substrate processing system having a substrate processing apparatus according to a first embodiment of the present invention.

FIG. 2 is a sectional view taken along line II-II in FIG. 1.

FIG. 3 is a flowchart showing substrate processing carried out by the substrate processing system shown in FIG. 1.

FIG. 4 is a sectional view of a second process module provided as a substrate processing apparatus according to a second embodiment of the present invention.

FIG. 5 is a flowchart showing substrate processing carried out by a substrate processing system having the substrate processing apparatus according to the second embodiment of the present invention.

### DETAILED DESCRIPTION OF THE PREFERRED EMBODIMENTS

The present invention will now be described in detail below with reference to the drawings showing preferred embodiments thereof.

First, a description will be made of a substrate processing system having a substrate processing apparatus according to a first embodiment of the present invention.

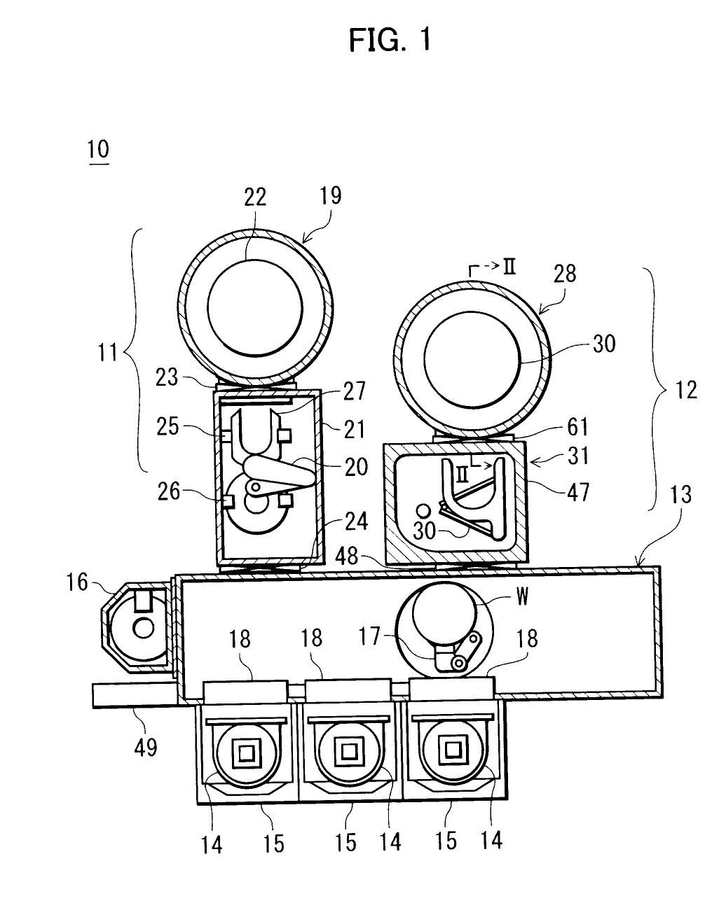

FIG. 1 is a plan view schematically showing the configuration of a substrate processing system having a substrate processing apparatus according to a present embodiment.

In FIG. 1, a substrate processing apparatus 10 has a first process ship 11 for performing a plasma processing on a wafer W (substrate) for semiconductor devices (hereinafter simply referred to as the “wafer W”), a second process ship 12 disposed parallel to the first process ship 11 to perform a chemical reaction treatment and a heating treatment on the plasma-treated wafer W, and a loader module 13 provided as a rectangular common transfer chamber to which the first and second process ships 11 and 12 are connected.

In addition to the first and second process ships 11 and 12, there are connected to the loader module 13 three FOUP mounting stages 15, on each of which is mounted a front opening unified pod (FOUP) 14 provided as a container for housing twenty-five wafers W, and an orienter 16 for pre-aligning the position of each wafer W transferred out from the FOUP 14.

The first and second process ships 11 and 12 are connected to a side wall of the loader module 13 along the longitudinal direction thereof and disposed opposite to the three FOUP mounting stages 15 with the loader module 13 positioned therebetween. The orienter 16 is disposed at one end of the loader module 13 with respect to the longitudinal direction thereof.

The loader module 13 includes a scalar-type dual arm transfer arm mechanism 17 disposed therein and adapted to transfer the wafers W, and three loading ports 18 disposed on a side wall of the loader module 13 in correspondence with the respective FOUP mounting stages 15 and provided as inlets for the wafers W to be loaded through. The transfer arm mechanism 17 takes a wafer W out from a FOUP 14 mounted on a FOUP mounting stage 15 through the corresponding loading port 18, and transfers the removed wafer W into and out of the first process ship 11, the second process ship 12, and the orienter 16.

The first process ship 11 has a first process module 19 for performing a plasma processing on a wafer W, and a first load lock module 21 containing a first link-type single pick transfer arm 20 for transferring the wafer W into and out of the first process module 19.

The first process module 19 has a cylindrical processing compartment (chamber) and upper and lower electrodes (not shown in the figure) disposed therein. The distance between the upper and lower electrodes is set so as to be appropriate for performing an etching processing on wafers W as a plasma processing. In addition, the lower electrode has in the top portion thereof an ESC 22 for chucking a wafer W by means of a coulomb force or the like.

In the first process module 19, a processing gas is introduced into the chamber and an electric field is generated between the upper and lower electrodes, whereby the introduced processing gas is turned into plasma to produce ions and radicals, thus performing etching processing on each wafer W using the ions and the radicals.

In the first process ship 11, the internal pressure of the first process module 19 is held at vacuum, whereas the internal pressure of the loader module 13 is held at atmospheric pressure. To this end, the first load lock module 21 has a vacuum gate valve 23 at a coupling part whereby the first load lock module 21 is coupled with the first process module 19, and an atmospheric gate valve 24 at a coupling part whereby the first load lock module 21 is coupled with the loader module 13. Thus, the first load lock module 21 is configured as a preliminary vacuum transfer chamber the internal pressure of which is adjustable.

Inside the first load lock module 21, the first transfer arm 20 is disposed in an approximately central portion of the module 21, a first buffer 25 is disposed closer to the first process module 19 than the first transfer arm 20, and a second buffer 26 is disposed closer to the loader module 13 than the first transfer arm 20. The first and second buffers 25 and 26 are disposed on a track along which moves a support portion (pick) 27 disposed at the leading end of the first transfer arm 20 to support a wafer W. An etch-treated wafer W is temporarily retracted above the track of the support portion 27, thereby enabling a smooth switch-over between the etch-treated wafer W and a wafer W to be etch-treated to take place in the first process module 19. The second process ship 12 has a second process module 28 (substrate processing apparatus) for performing a chemical reaction treatment and a heating treatment on a wafer W, and a second load lock module 31 connected to the second process module 28 through a vacuum gate valve 61 and containing a second link-type single pick transfer arm 30 for transferring a wafer W into and out of the second process module 28.

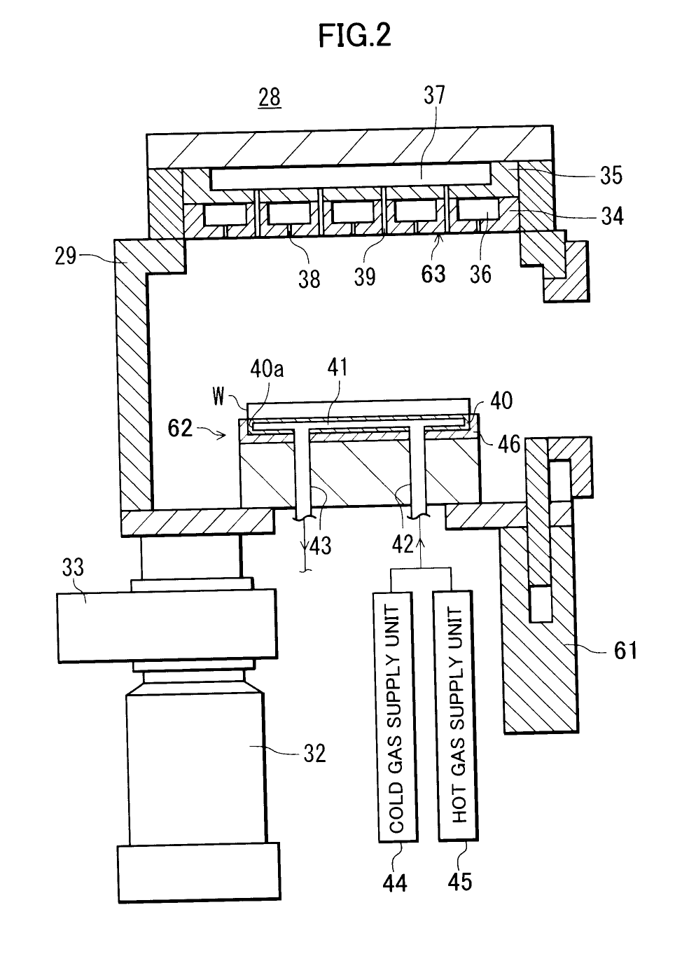

FIG. 2 is a sectional view taken along line II-II in FIG. 1.

In FIG. 2, the second process module 28 has a cylindrical processing compartment (chamber) 29, a mounting stage 62 disposed in the chamber 29 for mounting a wafer W thereon and for controlling the processing temperature of the mounted wafer W, a shower head 63 disposed so as to face the mounting stage 62 above the chamber 29, a turbo molecular pump (TMP) 32 for exhausting gases and the like within the chamber 29, and an adaptive pressure control (APC) valve 33 disposed between the chamber 29 and the TMP 32 as a variable butterfly valve for controlling the internal pressure of the chamber 29.

The shower head 62 is comprised of a disc-shaped lower-layer gas supply unit 34 and a disc-shaped upper-layer gas supply unit 35. The upper-layer gas supply unit 35 is disposed on top of the lower-layer gas supply unit 34. In addition, the lower-layer gas supply unit 34 has first buffer chambers 36 therein, and the upper-layer gas supply unit 35 has a second buffer chamber 37 therein. The first buffer chambers 36 and the second buffer chamber 37 are communicated with the chamber 29 through gas-passing holes 38 and 39, respectively.

The first buffer chambers 36 in the lower-layer gas supply unit 34 of the shower head 63 are connected to an inert gas supply system (not shown). The inert gas supply system supplies an inert gas, for example, an N₂ (nitrogen) gas into the first buffer chambers 36. The N₂ gas supplied into the first buffer chambers 36 is fed into the chamber 29 through the gas-passing holes 38.

On the other hand, the second buffer chamber 37 in the upper-layer gas supply unit 35 of the shower head 63 is connected to an HF (hydrogen fluoride) gas supply system (not shown). The HF gas supply system supplies an HF gas into the second buffer chamber 37. The HF gas supplied into the second buffer chamber 37 is fed into the chamber 29 through the gas-passing holes 39. The upper-layer gas supply unit 35 of the shower head 63 contains a heater (not shown), such as a heating element. This heating element controls the temperature of the HF gas within the second buffer chamber 37.

A jacket 40 (temperature control device) is disposed upwardly within the mounting stage 62 in a mounting surface thereof for mounting a wafer W thereon. The jacket 40 is formed of such a material as carbon, aluminum, copper, brass, iron, silver, aluminum nitride, silicon carbide, or the like having a large heat conductivity and a small specific heat capacity. In addition, the jacket 40 is formed so that the mass thereof is small, specifically the jacket 40 has a wall 40a formed so that the thickness thereof is no greater than 2 mm. Consequently, the jacket 40 is configured so as to have a high thermal conductance and a small heat capacity. Note that in the present embodiment, the thermal conductivity of the jacket 40 is preferably 80 W/m·K or greater.

The jacket 40 is delimited off by the wall 40a and has therein a gas inflow chamber 41 into which a cold gas or a hot gas is flowed. A gas inlet pipe 42 and a gas outlet pipe 43 are connected to this gas inflow chamber 41. To the upstream side of the gas inlet pipe 42, there are connected a cold gas supply unit 44 for supplying a cold gas of −20° C. or lower and a hot gas supply unit 45 for supplying a hot gas of 200° C. or higher, at a high rate into the gas inflow chamber 41 through the gas inlet pipe 42. Within the cold gas supply unit 44, a cold gas of −20° C. or lower is produced using, for example, an ultralow-temperature air generator (vortex tube). A dry gas, such as an N₂ gas, is used as the cold gas. Within the hot gas supply unit 45, a hot gas of 200° C. or higher is produced by heating a gas. As the aforementioned gas to be heated, a hot gas produced when producing a cold gas using a vortex tube may be used within the hot gas supply unit 45.

A heat-insulating material 46 formed so as to surround the jacket 40 is disposed upwardly within the mounting stage 62. The heat-insulating material 46 functions as a barrier for inhibiting heat conduction from the jacket 40 to the inside of the mounting stage 62.

In the second process module 28, the cold gas supply unit 44 supplies the aforementioned cold gas into the gas inflow chamber 41 at a high rate when performing a chemical reaction treatment on a wafer W. Consequently, the temperature of the jacket 40 is rapidly lowered by the temperature of the cold gas supplied at a high rate, and the temperature of the wafer W is rapidly lowered by the rapidly lowered temperature of the jacket 40. Thus, the processing temperature of the wafer W is set to a low temperature appropriate for a chemical reaction treatment. Also in the second process module 28, the hot gas supply unit 45 supplies the aforementioned hot gas into the gas inflow chamber 41 at a high rate when performing a heating treatment on the wafer W. Consequently, the temperature of the jacket 40 is rapidly raised by the temperature of the hot gas supplied at a high rate, and the temperature of the wafer W is rapidly raised by the rapidly raised temperature of the jacket 40. Thus, the processing temperature of the wafer W is set to a high temperature appropriate for a heating treatment.

Referring back to FIG. 1, the second load lock module 31 has a box-shaped transfer compartment (chamber) 47 containing the second transfer arm 30. In addition, the internal pressure of the second process module 28 is held at a pressure below atmosphere pressure, whereas the internal pressure of the loader module 13 is held at atmospheric pressure. To this end, the second load lock module 31 has a vacuum gate valve 61 at a coupling part whereby the second load lock module 31 is coupled with the second process module 28, and an atmospheric door valve 48 at a coupling part whereby the second load lock module 31 is coupled with the loader module 13. Thus, the second load lock module 31 is configured as a preliminary vacuum transfer chamber the internal pressure of which is adjustable.

In addition, the substrate processing system 10 has an operation panel 49 disposed at one end of the loader module 13 with respect to the longitudinal direction thereof. The operation panel 49 has a display unit comprised of, for example, a liquid crystal display (LCD), and the display unit displays the operating status of each component of the substrate processing system 10.

Next, a description will be made of substrate processing carried out by a substrate processing system having a substrate processing apparatus according to the present embodiment.

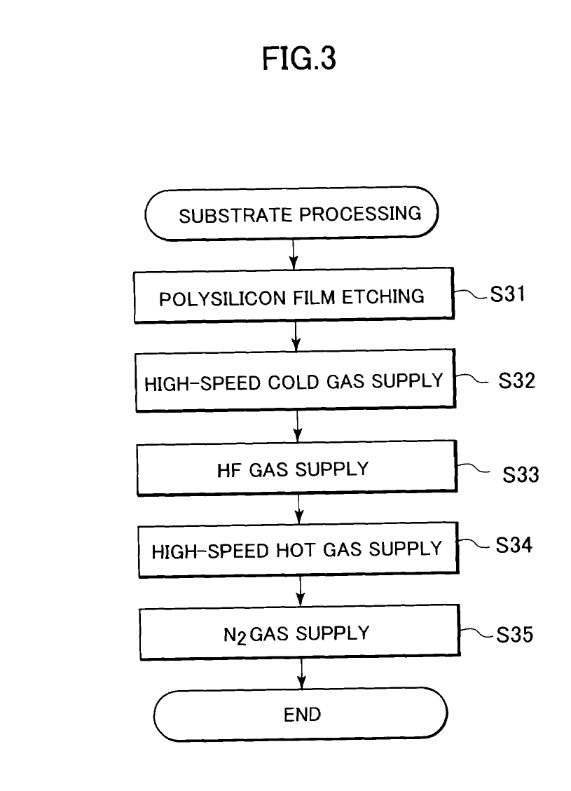

FIG. 3 is a flowchart showing substrate processing carried out by the substrate processing system 10 shown in FIG. 1.

First, there is prepared a wafer W wherein a polysilicon film is uniformly formed thereon and a hard mask is formed on the polysilicon film according to a predetermined pattern, so as to partially expose the polysilicon film. Then, the wafer W is conveyed into a chamber of the first process module 19 and is placed on the ESC 22.

Next, a processing gas is introduced into the chamber, and an electric field is generated between the upper electrode and the lower electrode, whereby the introduced processing gas is turned into plasma to produce ions and radicals, thus performing an etching processing on the exposed polysilicon film using the ions and the radicals (step S31). At this time, the polysilicon film is etched to form via holes and trenches and a deposit film composed of an SiOBr layer is formed on the side surfaces of the trenches thus formed. Note that the SiOBr layer is a pseudo-SiO₂ layer similar in nature to an SiO₂ layer.

Then, the wafer W is transferred out from the chamber of the first process module 19 and is transferred into the chamber 29 of the second process module 28 through the loader module 13. At this time, the wafer W is mounted on the mounting stage 62.

Next, the internal pressure of the chamber 29 is set to a pressure as high as 4000 Pa (30 Torr) or lower by the APC valve 33 and the like. Then, a cold gas of −20° C. or lower is supplied from the cold gas supply unit 44 into the gas inflow chamber 41 at a high rate (step S32). Consequently, the temperature of the jacket 40 is rapidly lowered by the temperature of the −20° C. or lower cold gas supplied at a high rate, and the temperature of the wafer W is lowered rapidly, specifically within 10 seconds, by the rapidly lowered temperature of the jacket 40. Thus, the processing temperature of the wafer W is set to a temperature ranging from 10 to 40° C.

Then, an HF gas is supplied toward the wafer W from the upper-layer gas supply unit 35 of the shower head 62 at a flow rate of 3000 SCCM (step S33). Here, the hard mask formed on the polysilicon film chemically reacts with the HF gas and is thus removed. In addition, the deposit layer formed on the side surfaces of the trenches chemically reacts with the HF gas to form into a liquid product (chemical reaction treatment). Specifically, the following chemical reaction is initiated:

SiO₂+6HF→H₂SiF₆+2H₂O

Thus, the deposit layer forms into a liquid product (H₂SiF₆ and H₂O).

Next, after the supply of the HF gas into the chamber 29 is stopped, a hot gas of 200° C. or higher is supplied from the hot gas supply unit 45 into the gas inflow chamber 41 at a high rate (step S34). Consequently, the temperature of the jacket 40 is rapidly raised by the temperature of the 200° C. or higher hot gas supplied at a high rate, and the temperature of the wafer W is raised rapidly, specifically within 10 seconds, by the rapidly raised temperature of the jacket 40. Thus, the processing temperature of the wafer W is set to a temperature ranging from 175 to 200° C. Here, the aforementioned liquid product vaporizes as the result of being heated (heating treatment). Specifically, the following chemical reaction is initiated:

H₂SiF₆→SiF₄↑+2HF↑

H₂O→H₂O↑

Thus, the liquid product turns into silicon tetrafluoride, hydrogen fluoride and water vapor, and then vaporizes.

Then, an N₂ gas is supplied from the lower-layer gas supply unit 34 of the shower head 31 into the chamber 29 as a purge gas (step S35), thereby exhausting the aforementioned vaporized gas from the chamber 29.

Next, the wafer W is transferred out from the chamber 29 of the second process module 28, thus terminating this substrate processing.

According to the substrate processing shown in FIG. 3, the temperature of the jacket 40 is rapidly lowered by the temperature of the −20° C. or lower cold gas as the result of the cold gas being supplied at a high rate from the cold gas supply unit 44 into the gas inflow chamber 41. On the other hand, the temperature of the jacket 40 is rapidly raised by the temperature of the 200° C. or higher hot gas as the result of the hot gas being supplied at a high rate from the hot gas supply unit 45 into the gas inflow chamber 41. In addition, the temperature of the wafer W within the substrate processing apparatus is controlled by the temperature of the jacket 40. Consequently, it is possible to rapidly raise and lower the processing temperature of the wafer W within one substrate processing apparatus. Thus, it is possible to promptly perform both a chemical reaction treatment and a heating treatment on the wafer W within one substrate processing apparatus. As a result, it is possible to eliminate one treatment apparatus from the substrate processing apparatus, thereby achieving efficient processing and cost reductions.

Next, a description will be made of a substrate processing system having a substrate processing apparatus according to a second embodiment of the present invention.

The present embodiment, which is basically the same in configuration and effect as the first embodiment described above, only differs from the first embodiment in the configuration of the mounting stage of the second process module. Accordingly, like constituent elements will not be explained again and only those constituent elements and effects different from those of the first embodiment will be described hereinafter.

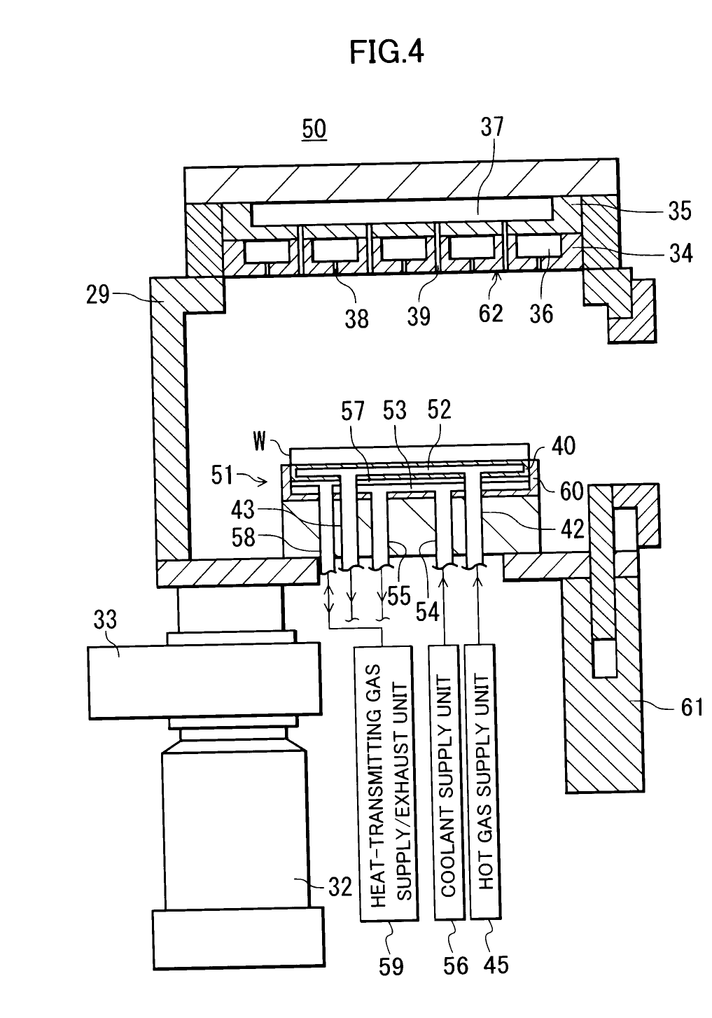

FIG. 4 is a sectional view of a second process module 50 provided as a substrate processing apparatus according to an embodiment of the present invention.

In FIG. 4, the second process module 50 (substrate processing apparatus) is disposed within the chamber 29 and has a mounting stage 51 for a wafer W to be mounted on and for controlling the processing temperature of the mounted wafer W.

A jacket 40 the same as that in the first embodiment is disposed upwardly within the mounting stage 51 in a surface thereof for a wafer W to be placed on. A gas inlet pipe 42 and a gas outlet pipe 43 are connected to the gas inflow chamber 52 of the jacket 40. To the upstream side of the gas inlet pipe 42, there is connected a hot gas supply unit 45 for supplying a hot gas of 200° C. or higher at a high rate into the gas inflow chamber 52 through the gas inlet pipe 42.

In addition, the mounting stage 51 has therein a coolant inflow chamber 53 whereinto a coolant is flowed, and a coolant inlet pipe 54 and a coolant outlet pipe 55 are connected to this coolant inflow chamber 53. To the upstream side of the coolant inlet pipe 54, there is connected a coolant supply unit 56 for constantly supplying a coolant of a predetermined temperature, for example, cooling water or a Galden fluid, into the coolant inflow chamber 53 through the coolant inlet pipe 54.

The mounting stage 51 is disposed between the jacket 40 and the coolant inflow chamber 53 and has therein a heat transmission/insulation switch-over chamber 57 into which a heat-transmitting gas is flowed and from which the heat-transmitting gas is vacuum-exhausted. A heat-transmitting gas inlet/outlet pipe 58 is connected to this heat transmission/insulation switch-over chamber 57. To the upstream side of the heat-transmitting gas inlet/outlet pipe 58, there is connected a heat-transmitting gas supply/exhaust unit 59 for supplying a heat-transmitting gas into the heat transmission/insulation switch-over chamber 57 or vacuum-exhausting the heat-transmitting gas within the heat transmission/insulation switch-over chamber 57 through the heat-transmitting gas inlet/outlet pipe 58.

A heat-insulating material 60 formed so as to surround the jacket 40, the heat transmission/insulation switch-over chamber 57 and the coolant inflow chamber 53 is disposed upwardly within the mounting stage 51. The heat-insulating material 60 functions as a barrier for inhibiting heat conduction from the jacket 40, the heat transmission/insulation switch-over chamber 57 and the coolant inflow chamber 53 to the inside of the mounting stage 51.

In the second process module 50, the heat-transmitting gas supply/exhaust unit 59 supplies a heat-transmitting gas into the heat transmission/insulation switch-over chamber 57 when performing a chemical reaction treatment on a wafer W. The supplied heat-transmitting gas transfers the temperature of a coolant supplied into the coolant inflow chamber 53 to the jacket 40. Consequently, the temperature of the jacket 40 is rapidly lowered by the temperature of the coolant and the temperature of the wafer W is rapidly lowered by the rapidly lowered temperature of the jacket 40. Thus, the processing temperature of the wafer W is set to a low temperature appropriate for a chemical reaction treatment. Also in the second process module 50, the heat-transmitting gas supply/exhaust unit 59 vacuum-exhausts the heat-transmitting gas within the heat transmission/insulation switch-over chamber 57 when performing a heating treatment on the wafer W. Consequently, the transfer of the temperature of the coolant supplied into the coolant inflow chamber 53 to the jacket 40 is cut off. At this time, the hot gas supply unit 45 supplies a 200° C. or higher hot gas into the gas inflow chamber 52 at a high rate. Consequently, the temperature of the jacket 40 is rapidly raised by the temperature of the hot gas supplied at a high rate and the temperature of the wafer W is rapidly raised by the rapidly raised temperature of the jacket 40. Thus, the processing temperature of the wafer W is set to a high temperature appropriate for a heating treatment.

Note that in the present embodiment, a cold gas supply unit for supplying a −20° C. or lower cold gas at a high rate through the gas inlet pipe 42 into the gas inflow chamber 52 may be connected to the upstream side of the gas inlet pipe 42. Then, the temperature of the jacket 40 may be lowered even more rapidly by not only cutting off heat transmission to the jacket 40 but also supplying the cold gas from the cold gas supply unit into the gas inflow chamber 52, when performing a chemical reaction treatment on the wafer W.

Next, a description will be made of substrate processing carried out by a substrate processing system having a substrate processing apparatus according to the present embodiment.

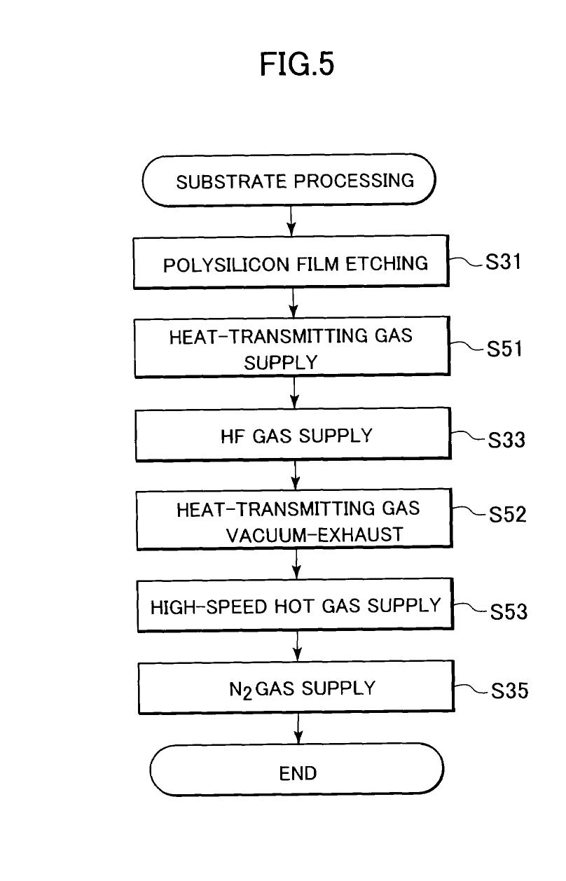

FIG. 5 is a flowchart showing substrate processing carried out by a substrate processing system having a substrate processing apparatus according to the present embodiment.

The substrate processing shown in FIG. 5 is basically the same as that shown in FIG. 3. Accordingly, the same steps as those of FIG. 3 are given like symbols and will not be explained again, and only the differences from the substrate processing shown in FIG. 3 will be explained hereinafter.

First, step S31 in the substrate processing shown in FIG. 3 is carried out. Next, a wafer W is transferred out from the chamber of the first process module 19 into the chamber 29 of the second process module 50 through the loader module 13. At this time the wafer is mounted on the mounting stage 51.

Next, the internal pressure of the chamber 29 is set to a pressure as high as 4000 Pa (30 Torr) or lower by the APC valve 33 and the like. Then, a heat-transmitting gas is supplied from the heat-transmitting gas supply/exhaust unit 59 into the heat transmission/insulation switch-over chamber 57 (step S51). The supplied heat-transmitting gas transfers the temperature of a coolant supplied into the coolant inflow chamber 53 to the jacket 40. Consequently, the temperature of the jacket 40 is rapidly lowered by the temperature of the coolant, and the temperature of the wafer W is lowered rapidly, specifically within 10 seconds, by the rapidly lowered temperature of the jacket 40. Thus, the processing temperature of the wafer W is set to a temperature ranging from 10 to 40° C. Then, step S33 in the substrate processing shown in FIG. 3 is carried out. After the supply of an HF gas into the chamber 29 is stopped, the heat-transmitting gas supply/exhaust unit 59 vacuum-exhausts the heat-transmitting gas within the heat transmission/insulation switch-over chamber 57 (step S52), thereby cutting off the transfer of the temperature of the coolant supplied into the coolant inflow chamber 53 to the jacket 40. In addition, the hot gas supply unit 45 supplies a 200° C. or higher hot gas into the gas inflow chamber 52 (step S53). Consequently, the temperature of the jacket 40 is rapidly raised by the temperature of the 200° C. or higher hot gas supplied at a high rate, and the temperature of the wafer W is raised rapidly, specifically within 10 seconds, by the rapidly raised temperature of the jacket 40. Thus, the processing temperature of the wafer W is set to a temperature ranging from 175 to 200° C.

Next, step S35 in the substrate processing shown in FIG. 3 is carried out and the wafer W is transferred out from the chamber 29 of the second process module 50, followed by terminating this substrate processing.

According to the substrate processing shown in FIG. 5, the temperature of the coolant supplied into coolant inflow chamber 53 is transferred to the jacket 40 as the result of the heat-transmitting gas being supplied from the heat-transmitting gas supply/exhaust unit 59 into the heat transmission/insulation switch-over chamber 57. Thus, the temperature of the jacket 40 is rapidly lowered by the temperature of the heat-transmitted coolant. On the other hand, the transfer of the temperature of the coolant supplied into the coolant inflow chamber 53 is cut off as the result of the heat-transmitting gas within the heat transmission/insulation switch-over chamber 57 being vacuum-exhausted by the heat-transmitting gas supply/exhaust unit 59. Then, the 200° C. or higher hot gas is supplied at a high rate by the hot gas supply unit 45 into the gas inflow chamber 52, and the temperature of the jacket 40 is rapidly raised by the temperature of the hot gas. In addition, the temperature of the wafer W within the substrate processing apparatus is controlled by the temperature of the jacket 40. Consequently, it is possible to achieve the same advantageous effect as that of the above-described first embodiment.

Although the substrate processing in each of the above-described embodiments is such that the temperature of a wafer is raised after having been lowered, the present invention is also applicable to substrate processing wherein the wafer temperature is lowered after having been raised according to a treatment performed on the wafer.

In addition, although a description has been made to a substrate processing system wherein two process ships are disposed in parallel, as a substrate processing system having the substrate processing apparatus according to each of the above-described embodiments, the substrate processing system is not limited to this configuration. Specifically, the substrate processing system may have a configuration wherein a plurality of process modules are disposed in tandem or in cluster form.

In addition, a substrate on which a chemical reaction treatment and a heating treatment are performed is not limited to a wafer for semiconductor devices, but may be other various types of substrates used for LCDs, flat panel displays (FPDs) or the like, or a photomask, a CD substrate, a printed board, or the like.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures and functions.

This application claims priority from Japanese Patent Application No. 2007-022331 filed Jan. 31, 2007, which is hereby incorporated by reference herein in its entirety.

What is claimed is:

1. A substrate processing apparatus having a mounting stage adapted to be mounted with a substrate and to control the processing temperature of said mounted substrate, said mounting stage comprising:
a temperature control device disposed in a mounting surface of said mounting stage for mounting the substrate thereon;
a coolant inflow chamber into which a coolant is flowed; and
a heat transmission/insulation switch-over chamber disposed between said temperature control device and said coolant inflow chamber so that a heat-transmitting gas is flowed into and vacuum-exhausted from said heat transmission/insulation switch-over chamber,
wherein said temperature control device has therein a gas inflow chamber into which a hot gas is flowed.

2. A substrate processing apparatus as claimed in claim 1, wherein a material composing a wall delimiting the gas inflow chamber is any one of carbon, aluminum, copper, brass, iron, silver, aluminum nitride, and silicon carbide.

3. A substrate processing apparatus as claimed in claim 2, wherein the thickness of the wall is not less than 2 mm.

4. A substrate processing apparatus as claimed in claim 2, wherein said hot gas is a 200° C. or higher hot gas.

5. A substrate processing apparatus having a mounting stage adapted to be mounted with a substrate and to control the processing temperature of said mounted substrate, said mounting stage comprising a temperature control device disposed in a mounting surface of said mounting stage for mounting said substrate thereon,
wherein said temperature control device has therein a gas inflow chamber into which a cold gas or a hot gas is flowed.

6. A substrate processing apparatus as claimed in claim 5, wherein a material composing a wall delimiting said gas inflow chamber is any one of carbon, aluminum, copper, brass, iron, silver, aluminum nitride, and silicon carbide.

7. A substrate processing apparatus as claimed in claim 6, wherein the thickness of the wall is not less than 2 mm.

8. A substrate processing apparatus as claimed in claim 5, wherein the temperature of the cold gas is not greater than −20° C. and the temperature of said hot gas is not less than 200° C.

9. A substrate processing apparatus as claimed in claim 5, wherein the cold gas is a dry gas.
